(19) United States
(12) Patent Application Publication
(10) Pub. No.: US 2025/0192040 A1
(43) Pub. Date: Jun. 12, 2025

(54) SEMICONDUCTOR DEVICE AND METHOD OF FABRICATING THE SAME

(71) Applicant: Samsung Electronics Co., Ltd., Suwon-si (KR)

(72) Inventors: Sangjine PARK, Suwon-si (KR); Youngtae KIM, Suwon-si (KR); Yongjae KIM, Suwon-si (KR)

(73) Assignee: Samsung Electronics Co., Ltd., Suwon-si (KR)

(21) Appl. No.: 18/678,374

(22) Filed: May 30, 2024

(30) Foreign Application Priority Data
Dec. 6, 2023 (KR) 10-2023-0175748

(51) Int. Cl. H01L 23/528; H01L 29/06; H01L 29/417; H01L 29/423; H01L 29/775; H01L 29/786

(52) U.S. Cl. CPC H01L 23/5283; H01L 23/5286; H10D 30/43; H10D 30/6729; H10D 30/6735; H10D 30/6757; H10D 62/121

(57) ABSTRACT

A semiconductor device may include a substrate, a lower power line buried in the substrate and extended in a first direction parallel to a bottom surface of the substrate, a source/drain pattern on the substrate, and a backside contact structure provided to penetrate the substrate and electrically connect the lower power line to the source/drain pattern. The backside contact structure may include a backside via pattern and a backside conductive contact, which are sequentially provided on the lower power line. A side surface of the backside conductive contact may be convex in an outward direction from an inner portion of the backside conductive contact toward an outside. A width of the backside conductive contact in the first direction may be the largest at a first level and may increase as a distance from the source/drain pattern increases in a direction toward the first level.

### CROSS-REFERENCE TO RELATED APPLICATIONS

This U.S. non-provisional patent application claims priority under 35 U.S.C. § 119 to Korean Patent Application No. 10-2023-0175748, filed on Dec. 6, 2023, in the Korean Intellectual Property Office, the entire contents of which are hereby incorporated by reference.

### BACKGROUND OF THE INVENTION

Various example embodiments relate to a semiconductor device and a method of fabricating the same, and in particular, to a semiconductor device including a field effect transistor and a method of fabricating the same.

A semiconductor device includes an integrated circuit consisting of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize high-performance semiconductor devices.

### SUMMARY

Various example embodiments of inventive concepts provide a semiconductor device with improved electrical characteristics and productivity and a method of fabricating the same.

Some example embodiments of inventive concepts relate to a semiconductor device may include a substrate, a lower power line buried in the substrate and extending in a first direction parallel to a bottom surface of the substrate, a source/drain pattern on the substrate, and a backside contact structure provided to penetrate the substrate and electrically connect the lower power line to the source/drain pattern. The backside contact structure may include a backside via pattern and a backside conductive contact sequentially arranged on the lower power line. A side surface of the backside conductive contact may be convex in an outward direction from an inner portion of the backside conductive contact toward an outside. A width of the backside conductive contact in the first direction may be greater at a first level, such that the width of the backside conductive contact in the first direction may increase as a distance from the source/drain pattern increases in a direction toward the first level.

Some example embodiments of inventive concepts relate to a semiconductor device may include a substrate, a lower power line buried in the substrate and extending in a first direction parallel to a bottom surface of the substrate, a source/drain pattern on the substrate, and a backside contact structure penetrating the substrate and electrically connecting the lower power line to the source/drain pattern. The backside contact structure may include a backside via pattern and a backside conductive contact sequentially arranged on the lower power line. The backside conductive contact may include a first region having a width in the first direction that increases as a distance from the source/drain pattern increases in a downward direction and a second region having a width in the first direction that decreases as a distance from the first region increases in a downward direction.

Some example embodiments of inventive concepts relate to a semiconductor device may include a substrate, a lower power line in the substrate and extending parallel to a bottom surface of the substrate, a source/drain pattern on the substrate, a channel pattern on the substrate, the channel pattern including a plurality of semiconductor patterns stacked to be spaced apart from each other, a gate electrode between the plurality of semiconductor patterns, and a backside contact structure penetrating the substrate and electrically connecting the lower power line to the source/drain pattern. The backside contact structure may include a backside via pattern and a backside conductive contact sequentially arranged on the lower power line. A side surface of the backside conductive contact may be convex in an outward direction from an inner portion of the backside conductive contact toward an outside. A width of the backside conductive contact measured in a first direction parallel to the bottom surface of the substrate, may be greater at a first level and may increase as a distance from the source/drain pattern increases in a direction toward the first level.

### BRIEF DESCRIPTION OF THE DRAWINGS

FIG. 1 is a plan view illustrating a semiconductor device according to an example embodiment.

FIGS. 2A to 2C are sectional views taken along lines A-A′, B-B′, and C-C′ of FIG. 1, respectively.

FIG. 3 is an enlarged view corresponding to a portion ‘Pl’ of FIG. 2A.

FIGS. 4A to 4C are sectional views taken along lines A-A′, B-B′, and C-C′ of FIG. 1, respectively.

FIG. 5 is an enlarged sectional view corresponding to a portion ‘P2’ of FIG. 4A.

FIGS. 6A to 14B are sectional views illustrating a method of fabricating a semiconductor device according to an example embodiment.

FIGS. 15A and 15B are sectional views illustrating a method of fabricating a semiconductor device according to an example embodiment.

FIGS. 16 and 17 are sectional views illustrating a method of fabricating a semiconductor device according to an example embodiment.

### DETAILED DESCRIPTION

Various example embodiments of inventive concepts will now be described more fully with reference to the accompanying drawings, in which some example embodiments are shown.

It will be understood that when an element is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” respectively, with regard to the other elements and/or properties thereof.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

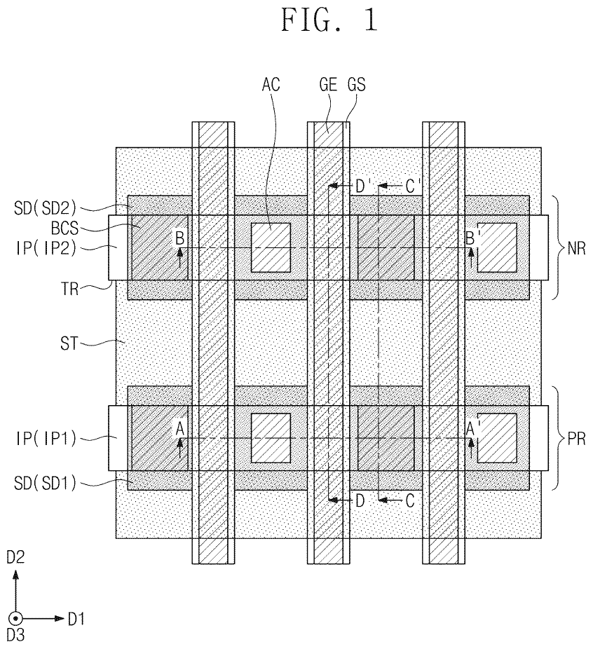

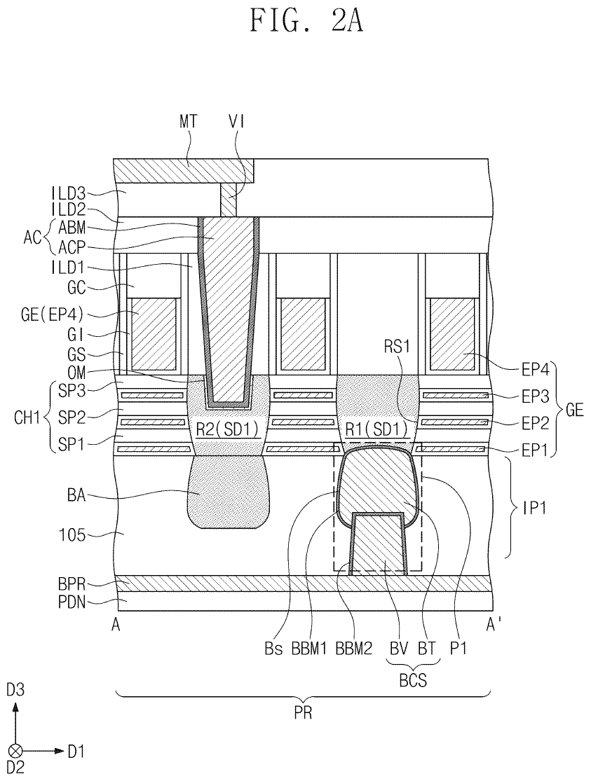

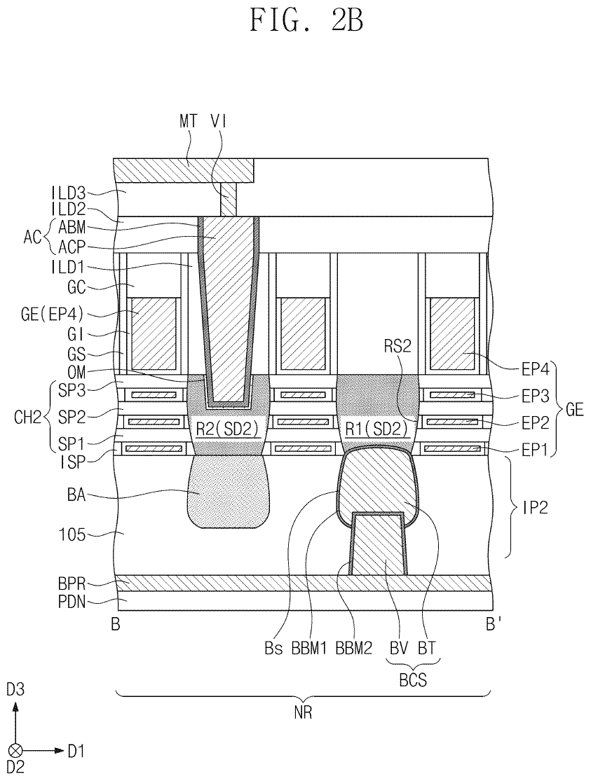

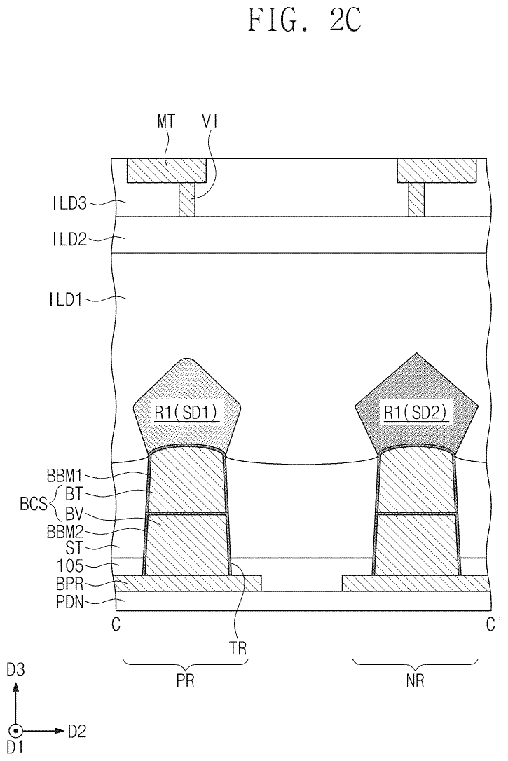

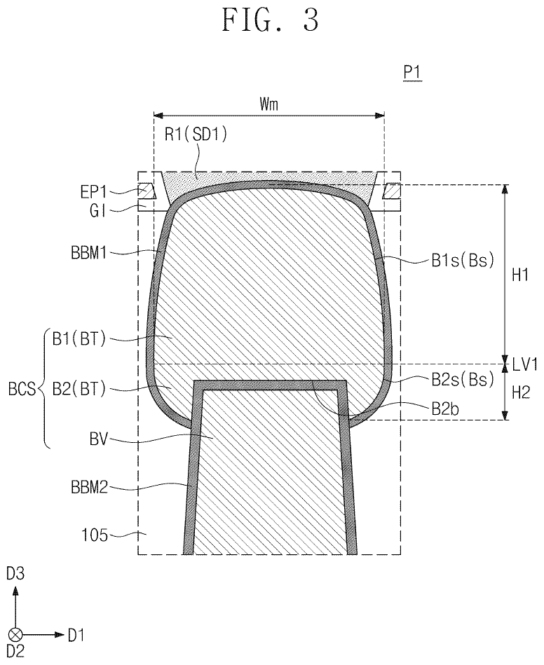

FIG. 1 is a plan view illustrating a semiconductor device according to an example embodiment. FIGS. 2A to 2C are sectional views taken along lines A-A′, B-B′, and C-C′ of FIG. 1. FIG. 3 is an enlarged sectional view corresponding to a portion ‘P1’ of FIG. 2A.

Referring to FIGS. 1 and 2A to 2C, a substrate 105 including a PMOSFET region PR and a NMOSFET region NR may be provided. In an example embodiment, the substrate 105 may include a silicon-based insulating layer. For example, the substrate 105 may be an insulating substrate. For example, the substrate 105 may include at least one of a silicon oxide layer (SiO₂), a silicon nitride layer (SiN), or a silicon oxynitride layer (SiON). In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements. A lower power line BPR may be provided in the insulating layer of the substrate 105, as will be described later.

The PMOSFET and NMOSFET regions PR and NR may be extended in a first direction D1 and may be spaced apart from each other in a second direction D2. The first and second directions D1 and D2 may be parallel to a bottom surface of the substrate 105 and may be non-parallel (e.g., orthogonal) to each other.

An insulating pattern IP may be defined by a trench TR, which is formed in an upper portion of the substrate 105. The insulating pattern IP may be a portion of the substrate 105. For example, the portion of the substrate 105 may protrude in a third direction D3. The third direction D3 may be a direction perpendicular to the bottom surface of the substrate 105. In the present specification, for the sake of convenience in explanation, the term “substrate 105” may refer to the remaining portion of the substrate 105, excluding the afore-described portion (e.g., the insulating pattern IP) of the substrate 105, unless otherwise stated. The insulating pattern IP may include a first insulating pattern IP1, which is provided on the PMOSFET region PR, and a second insulating pattern IP2, which is provided on the NMOSFET region NR. The first and second insulating patterns IP1 and IP2 may be extended in the second direction D2.

A device isolation pattern ST may be provided on the substrate 105 to cover the trench TR. The device isolation pattern ST may be provided to surround the first and second insulating patterns IP1 and IP2. The device isolation pattern ST may include an insulating material. As an example, the device isolation pattern ST may be formed of or include silicon oxide (SiO₂).

A first channel pattern CH1 may be provided on the first insulating pattern IP1, and a second channel pattern CH2 may be provided on the second insulating pattern IP2. In an example embodiment, a plurality of first channel patterns CH1 may be provided to be spaced apart from each other in the first direction D1. In an example embodiment, a plurality of second channel patterns CH2 may be provided to be spaced apart from each other in the first direction

D1. Each of the first and second channel patterns CH1 and CH2 may include a first semiconductor pattern SP1, a second semiconductor pattern SP2, and a third semiconductor pattern SP3, which are adjacent to each other in the third direction D3, but example embodiments are not limited thereto. In an example embodiment, each of the first and second channel patterns CH1 and CH2 may include four or more semiconductor patterns. In an example embodiment, each of the first to third semiconductor patterns SP1, SP2, and SP3 may be formed of or include crystalline silicon.

First recesses RS1 may be defined between the first channel patterns CH1, which are adjacent to each other in the first direction D1. Second recesses RS2 may be defined between the second channel patterns CH2, which are adjacent to each other in the first direction DI.

A first source/drain pattern SD1 may be provided on the first insulating pattern IP1, and a second source/drain pattern SD2 may be provided on the second insulating pattern IP2. The first source/drain pattern SD1 may fill the first recess RS1, and the second source/drain pattern SD2 may fill the second recess RS2. Each of the first and second source/drain patterns SD1 and SD2 may be electrically connected to the first to third semiconductor patterns SP1, SP2, and SP3. The first source/drain patterns SD1 may be impurity regions of a first conductivity type (e.g., p-type), and the second source/drain patterns SD2 may be impurity regions of a second conductivity type (e.g., n-type). In an example embodiment, a pair of the first source/drain patterns SD1 may be electrically connected to each other through the first channel pattern CH1. A pair of the second source/drain patterns SD2 may be electrically connected to each other through the second channel pattern CH2.

The first source/drain patterns SD1 may be formed of or include a semiconductor material (e.g., SiGe) whose lattice constant is greater than that of the first channel pattern CH1. In some example embodiments, the pair of the first source/drain patterns SD1 may exert a compressive stress on the first channel patterns CH1 therebetween. The second source/drain patterns SD2 may be formed of or include the same semiconductor material (e.g., Si) as the second channel pattern CH2.

The first and second source/drain patterns SD1 and SD2 may include a first pattern R1, which is electrically connected to a lower power line BPR to be described below, and a second pattern R2, which is electrically connected to an active contact AC to be described below. As an example, the first and second patterns R1 and R2 may be used as drain and source regions, respectively, of a transistor, but example embodiments are not limited thereto. For example, the first pattern R1 may be used as the source region of the transistor, and the second pattern R2 may be used as the drain region of the transistor.

A gate electrode GE may be provided on the first and second channel patterns CH1 and CH2 to cross the first and second channel patterns CH1 and CH2. In an example embodiment, a plurality of gate electrodes GE may be provided. The gate electrodes GE may be extended in the second direction D2 and may be spaced apart from each other in the first direction D1.

The gate electrode GE may include an inner electrode and an outer electrode. The inner electrode of the gate electrode GE may be provided between the uppermost one of the semiconductor patterns SP1, SP2, and SP3 and the insulating pattern IP. The outer electrode of the gate electrode GE may be provided on the uppermost one of the semiconductor patterns. The inner electrode of the gate electrode GE may include a first electrode portion EP1, a second electrode portion EP2, and a third electrode portion EP3, but example embodiments are not limited thereto. In an example embodiment, the inner electrode of the gate electrode GE may include four or more electrode portions. For example, the first electrode portion EP1 may be interposed between the insulating pattern IP and the first semiconductor pattern SP1. The second electrode portion EP2 may be interposed between the first semiconductor pattern SP1 and the second semiconductor pattern SP2. The third electrode portion EP3 may be interposed between the second semiconductor pattern SP2 and the third semiconductor pattern SP3. The outer electrode of the gate electrode GE may include a fourth electrode portion EP4. In an example embodiment, the fourth electrode portion EP4 may be provided on the third semiconductor pattern SP3.

The gate electrode GE may include a first metal pattern and a second metal pattern on the first metal pattern. The first metal pattern may include a work-function metal, which can be used to adjust a threshold voltage of the transistor. In an example embodiment, the first metal pattern may be formed of or include at least one of metallic materials (e.g., Ti, Mo, W, Cu, Al, Ta, Ru, Ir, and Co) or metal nitride materials (e.g., nitride materials of Ti, Mo, W, Cu, Al, Ta, Ru, Ir, and Co). In an example embodiment, the first metal pattern may further include carbon (C). In an example embodiment, the first metal pattern may include metallic materials having different work functions.

The second metal pattern may include a metallic material (e.g., Ti, Mo, W, Cu, Al, Ta, Ru, Ir, and Co) whose resistance is lower than that of the first metal pattern.

The first to third electrode portions EP1, EP2, and EP3 of the gate electrode GE may include the first metal pattern. The fourth electrode portion EP4 of the gate electrode GE may include the first metal pattern and the second metal pattern.

A gate capping pattern GC may be provided on a top surface of the gate electrode GE. The gate capping pattern GC may be formed of or include at least one of SiON, SiCN, SiOCN, or SiN.

Gate spacers GS may be provided on side surfaces of the fourth electrode portion EP4 of the gate electrode GE and may be extended to cover respective side surfaces of the gate capping pattern GC. The gate spacer GS may include a single layer or a composite layer. In an example embodiment, the gate spacer GS may be formed of or include at least one of SiON, SiCN, SiOCN, or SiN.

A gate insulating pattern GI may be interposed between the gate electrode GE and the first to third semiconductor patterns SP1, SP2, and SP3. The gate insulating pattern GI may cover a top surface, a bottom surface, and opposite side surfaces of each of the first to third semiconductor patterns SP1, SP2, and SP3. The gate insulating pattern GI may cover a top surface of the device isolation pattern ST below the gate electrode GE. The gate insulating pattern GI may be interposed between the fourth electrode portion EP4 and the gate spacer GS. The gate insulating pattern GI may be formed of or include at least one of, for example, silicon oxide (SiO₂), silicon oxynitride (SiON), or high-k dielectric materials. In the present specification, the high-k dielectric material may be defined as a material having a dielectric constant higher than that of silicon oxide.

An inner spacer ISP may be interposed between the second source/drain pattern SD2 and the side surface of the gate electrode GE. For example, the inner spacer ISP may be interposed between the inner electrode and the second source/drain pattern SD2. The inner spacer ISP may include an insulating material.

A first interlayer insulating layer ILD1 may be provided on the substrate 105. The first interlayer insulating layer ILD1 may cover the gate spacers GS and the first and second source/drain patterns SD1 and SD2. A top surface of the first interlayer insulating layer ILD1 may be located at substantially the same level as the top surface of the gate capping pattern GC and the top surface of the gate spacer GS.

A second interlayer insulating layer ILD2 may be provided on the first interlayer insulating layer ILD1 to cover the gate capping pattern GC. A third interlayer insulating layer ILD3 may be provided on the second interlayer insulating layer ILD2. In an example embodiment, the first to third interlayer insulating layers ILD1, ILD2, and ILD3 may be formed silicon oxide (SiO₂).

The active contact AC may be provided to penetrate the first and second interlayer insulating layers ILD1 and ILD2 in the third direction D3. In an example embodiment, a plurality of active contacts AC may be provided, and each of the active contacts AC may include a lower portion that is inserted in an upper portion of the second pattern R2 of the source/drain pattern SD1 or SD2.

The active contact AC may include a conductive pattern ACP, which is provided to penetrate the first and second interlayer insulating layers ILD1 and ILD2, and a barrier pattern ABM, which is provided to enclose the conductive pattern ACP. In an example embodiment, the conductive pattern ACP may be formed of or include at least one of metallic materials (e.g., Ti, Mo, W, Cu, Al, Ta, Ru, Ir, and Co). The barrier pattern ABM may be formed of or include at least one of metal nitride materials (e.g., nitride materials of Ti, Mo, W, Cu, Al, Ta, Ru, Ir, and Co).

An ohmic pattern OM may be interposed between the active contact AC and the second pattern R2 of the source/drain pattern SD1 or SD2. Thus, it may be possible to improve a contact resistance property between the active contact AC and the second pattern R2 of the source/drain pattern SD1 or SD2. The ohmic pattern OM may be formed of or include at least one of metal silicide materials (e.g., silicide materials of Ti, Mo, W, Cu, Al, Ta, Ru, and Ir).

Metal patterns MT may be provided in the third interlayer insulating layer ILD3. Vias VI may be interposed between the metal patterns MT and the active contacts AC. The metal patterns MT may be electrically connected to the active contacts AC through the vias VI. In an example embodiment, gate contacts (not shown) may be connected to the gate electrodes GE, and the metal patterns MT may be electrically connected to the gate contacts through the vias VI. In an example embodiment, although not illustrated in the drawings, the metal patterns MT and the vias VI may be alternately stacked to form a multi-layered structure. The metal patterns MT and the vias VI may be formed of or include at least one of metallic materials (e.g., Ti, Mo, W, Cu, Al, Ta, Ru, Ir, and Co).

The lower power line BPR may be provided in the substrate 105. The lower power line BPR may be buried in the substrate 105 and may be extended in the first direction DI. In an example embodiment, a plurality of lower power lines BPR may be provided to be adjacent to each other in the second direction D2. The lower power line BPR may be formed of or include at least one of metallic materials (e.g., Ti, Mo, W, Cu, Al, Ta, Ru, Ir, and Co).

A backside conductive structure BCS may be provided in the substrate 105. The backside conductive structure BCS may penetrate the substrate 105 and may be interposed between the first pattern R1 of the source/drain pattern SD1 or SD2 and the lower power line BPR. The backside conductive structure BCS may be provided to electrically connect the first pattern R1 of the source/drain pattern SD1 or SD2 to the lower power line BPR.

The backside conductive structure BCS may include a backside via pattern BV and a backside conductive contact BT, which are sequentially provided on the lower power line BPR. In an example embodiment, the backside via pattern BV and the backside conductive contact BT may be formed of or include at least one of metallic materials (e.g., Ti, Mo, W, Cu, Al, Ta, Ru, Ir, and Co). A width of the backside via pattern BV in the first direction D1 may decrease as a height in the third direction D3 increases.

A first backside barrier pattern BBM1 may cover top and side surfaces of the backside conductive contact BT. The first backside barrier pattern BBM1 may be interposed between the first pattern RI of the source/drain pattern SD1 or SD2 and the backside conductive contact BT.

A second backside barrier pattern BBM2 may cover top and side surfaces of the backside via pattern BV. The second backside barrier pattern BBM2 may be interposed between the backside via pattern BV and the backside conductive contact BT. Each of the first and second backside barrier patterns BBM1 and BBM2 may be formed of or include at least one of metal nitride materials (e.g., nitride materials of Ti, Mo, W, Cu, Al, Ta, Ru, Ir, and Co).

Referring to FIG. 3, the backside conductive contact BT may have the largest width in the first direction D1, at a first level LV1. The width of the backside conductive contact BT in the first direction D1 may increase as a distance from the first pattern R1 of the first source/drain pattern SD1 increases in a direction toward the first level LV1. The width of the backside conductive contact BT in the first direction D1 may decrease as a distance from the first level LV1 increases in a downward direction (e.g., an opposite direction of the third direction D3).

The backside conductive contact BT may include a first region B1, which is placed at a level higher than the first level LV1, and a second region B2, which is placed at a level lower than the first level LV1. The first region B1 may be a portion of the backside conductive contact BT whose width in the first direction D1 increases in the downward direction. The second region B2 may be the other portion of the backside conductive contact BT whose width in the first direction D1 decreases in the downward direction. At the first level LV1, the first region B1 and the second region B2 may be connected to each other without any interfacial surface or boundary therebetween.

The backside conductive contact BT may have the largest width Wm in the first direction D1, at a height lower than half a height of the backside conductive contact BT. Accordingly, a height H1 from the first level LV1 to the uppermost surface of the backside conductive contact BT may be larger than a height H2 from the lowermost surface of the backside conductive contact BT to the first level LV1. In other words, the height H1 of the first region B1 may be larger than the height H2 of the second region B2. In some example embodiments, when viewed in a section taken parallel to the first direction D1, an area of the first region B1 may be larger than an area of the second region B2.

A side surface Bs of the backside conductive contact BT may be convex in an outward direction from an inner portion of the backside conductive contact BT toward the outside of the backside conductive contact BT. The side surface Bs of the backside conductive contact BT may include a first side surface B1s and a second side surface B2s. For example, the first side surface B1s may be a side surface of the first region B1, and the second side surface B2s may be a side surface of the second region B2. A curvature of the second side surface B2s may be larger than a curvature of the first side surface B1s.

An upper portion of the backside via pattern BV may be buried in the backside conductive contact BT. For example, the upper portion of the backside via pattern BV may be buried in the second region B2 of the backside conductive contact BT, but example embodiments are not limited thereto. The upper portion of the backside via pattern BV may be enclosed by the backside conductive contact BT. A top surface of the backside via pattern BV may be completely covered (or may be covered) with the backside conductive contact BT.

The backside conductive contact BT and the backside via pattern BV described with reference to FIG. 3 may be configured to have substantially the same features as the backside conductive contact BT and the backside via pattern BV of FIG. 3B.

Referring back to FIGS. 1 and 2A to 2C, a backside alignment pattern BA may be buried in the substrate 105 and may be provided below the second pattern R2 of the source/drain pattern SD1 or SD2. The second pattern R2 of the source/drain pattern SD1 or SD2 may overlap vertically and be in contact with the backside alignment pattern BA. As a distance from the second pattern R2 of the source/drain pattern SD1 or SD2 increases in a downward direction, a width, in the first direction D1, of the backside alignment pattern BA may increase and then decrease. A side surface of the backside alignment pattern BA may be convex in an outward direction from an inner portion of the backside alignment pattern BA toward the outside of the backside alignment pattern BA. In an example embodiment, the backside alignment pattern BA may be formed of or include silicon-germanium (SiGe). The backside alignment pattern BA may be spaced apart from the lower power line BPR by the substrate 105.

A power delivery network layer PDN may be provided on the bottom surface of the substrate 105. The power delivery network layer PDN may include a plurality of lower interconnection lines (not shown), which are electrically connected (or are connected) to the lower power line BPR. In an example embodiment, the power delivery network layer PDN may include an interconnection network, which is used to apply a source voltage. In an example embodiment, the power delivery network layer PDN may include an interconnection network, which is used to apply a drain voltage.

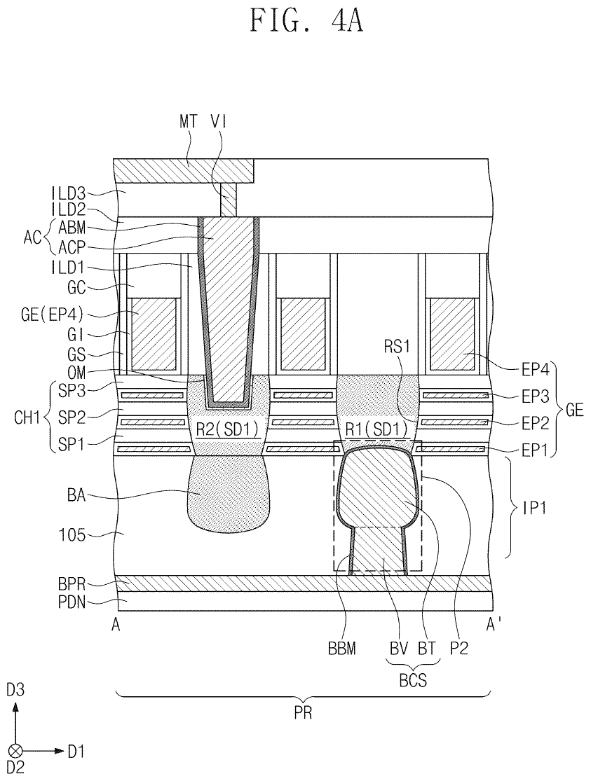

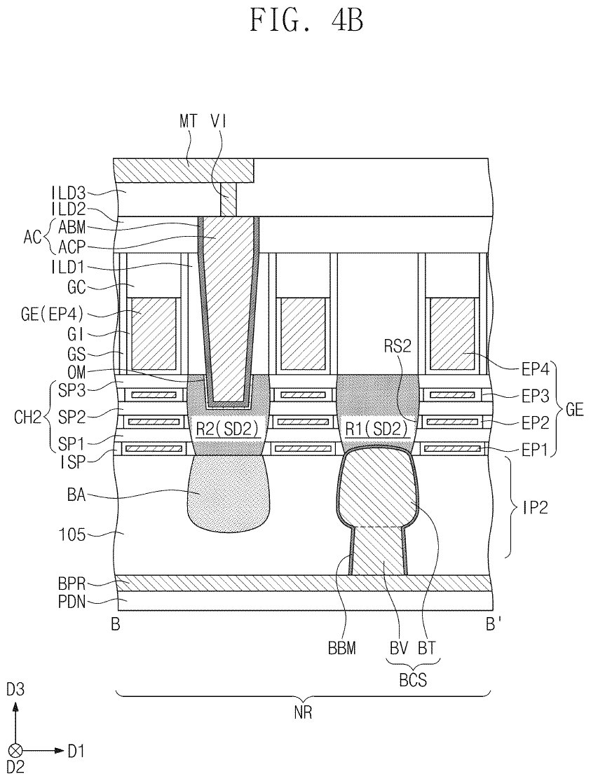

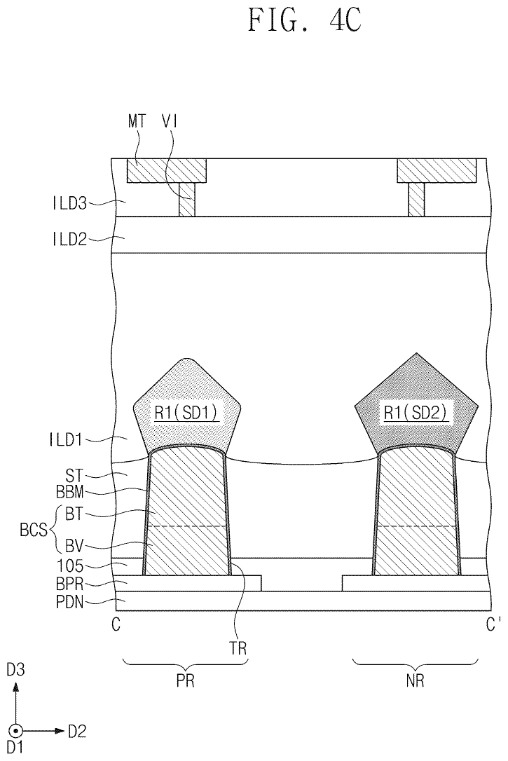

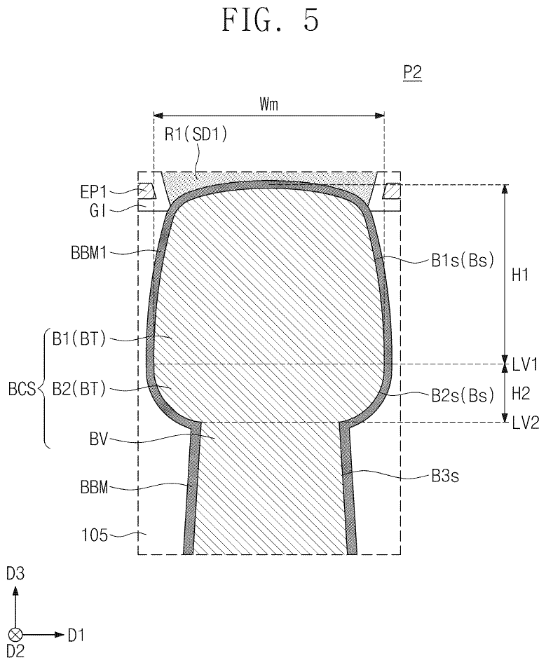

Hereinafter, a semiconductor device according to an example embodiment of inventive concepts will be described in more detail with reference to FIGS. 4A to 5. In the following description, a previously-described element may be identified by the same reference number without repeating an overlapping description thereof, for concise description.

FIGS. 4A to 4C are sectional views taken along lines A-A′, B-B′, and C-C′ of FIG. 1, respectively. FIG. 5 is an enlarged sectional view corresponding to a portion ‘P2’ of FIG. 4A.

Referring to FIGS. 4A to 5, the backside conductive structure BCS may include the backside conductive contact BT, which is placed at a level higher than a second level LV2, and the backside via pattern BV, which is placed at a level lower than the second level LV2. The second level LV2 may be defined as a level at which the width of the backside conductive structure BCS measured in the first direction DI decreases and then increases. At the second level LV2, the backside conductive contact BT and the backside via pattern BV may be connected to each other without any interfacial surface or boundary therebetween.

The side surface Bs of the backside conductive contact BT may be continuously connected (or may be connected) to a side surface B3s of the backside via pattern BV. Unlike the side surface Bs of the backside conductive contact BT, the side surface B3s of the backside via pattern BV may have a substantially linear profile.

The backside conductive contact BT may include the first region B1, which is placed at a level higher than the first level LV1, and the second region B2, which is placed between the first and second levels LV1 and LV2. Unlike the example shown in FIGS. 2A to 3, the backside via pattern BV may not be buried in the second region B2 of the backside conductive contact BT.

A backside barrier pattern BBM may be provided to enclose and cover side surfaces of the backside conductive contact BT and the backside via pattern BV.

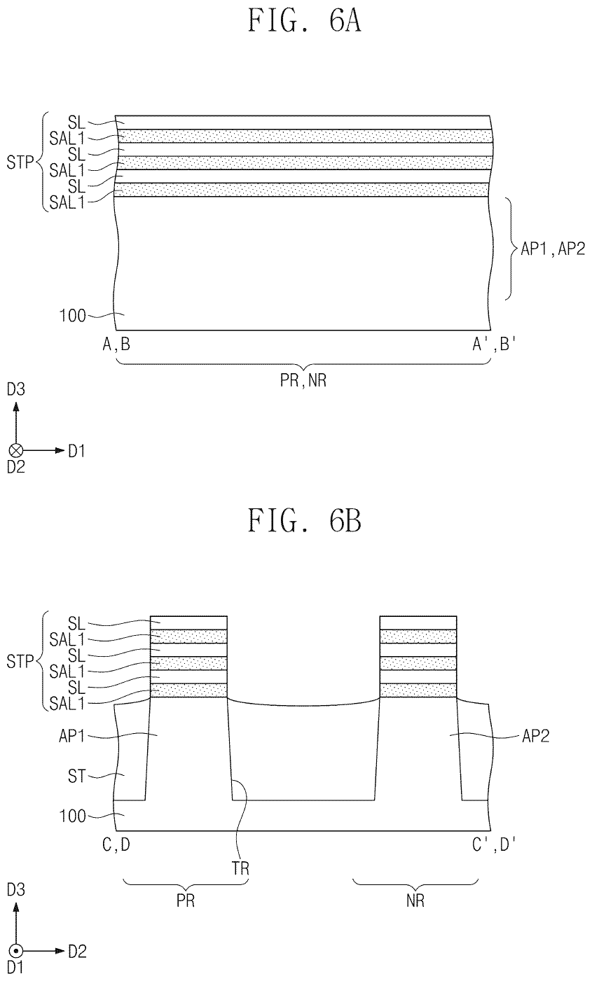

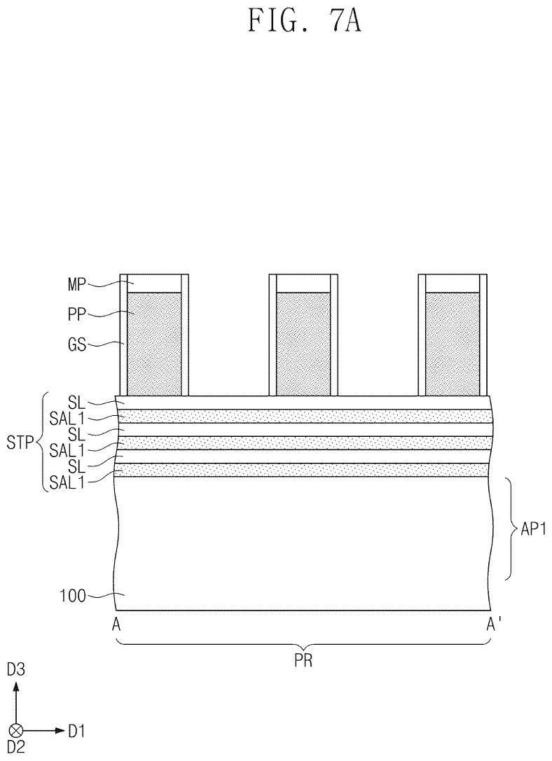

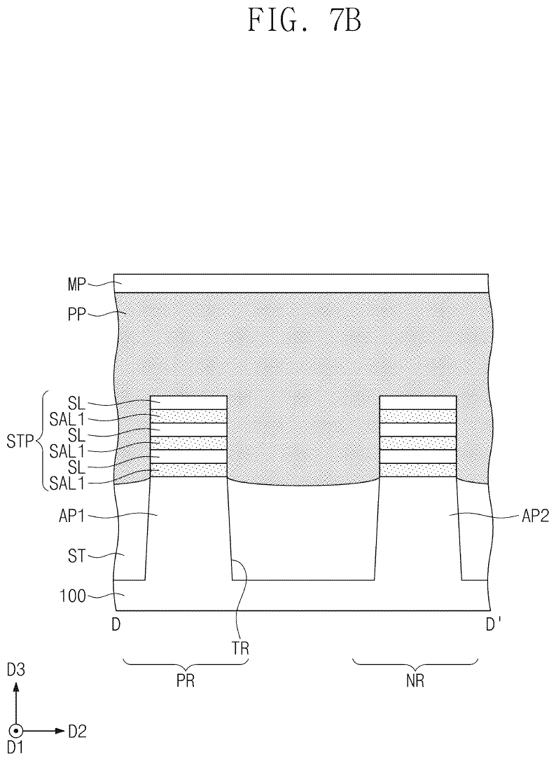

FIGS. 6A to 14B are sectional views illustrating a method of fabricating a semiconductor device according to an example embodiment.

Referring to FIGS. 1, 6A, and 6B, a semiconductor substrate 100 including the PMOSFET and NMOSFET regions PR and NR may be provided. In an example embodiment, the semiconductor substrate 100 may be a single crystalline silicon substrate, a silicon-germanium substrate, or a semiconductor substrate (e.g., a silicon-on-insulator (SOI) substrate) including a semiconductor material. Stacking patterns STP may be formed on the PMOSFET and NMOSFET regions PR and NR. In an example embodiment, the formation of the stacking patterns STP may include alternately stacking semiconductor layers SL and first sacrificial layers SAL1 on the semiconductor substrate 100, forming mask patterns (not shown) extending in the first direction D1, and performing a patterning process using the mask patterns as etch mask. During the patterning process, the semiconductor substrate 100 may also be partially removed to form the trenches TR defining a first active pattern AP1 and a second active pattern AP2.

The first active pattern AP1 may be formed on the PMOSFET region PR, and the second active pattern AP2 may be formed on the NMOSFET region NR. The first and second active patterns AP1 and AP2 may be extended in the second direction D2. The device isolation patterns ST may be formed to fill the trenches TR.

The first sacrificial layers SAL1 may be formed of or include a material having an etch selectivity with respect to the semiconductor layers SL. In some example embodiments, it may be possible to prevent the semiconductor layers SL from being removed or excessively etched in a subsequent process of removing the first sacrificial layers SAL1 (or may be possible to reduce a possibility of the semiconductor layers SL from being removed or excessively etched in a subsequent process of removing the first sacrificial layers SAL1). In an example embodiment, each of the semiconductor layer SL and the first sacrificial layer SAL1 may be formed of or include at least one of silicon (Si), germanium (Ge), or silicon germanium (SiGe), but the material of the semiconductor layers SL may be different from that of the first sacrificial layers SAL1.

Referring to FIGS. 1, 7A, and 7B, sacrificial patterns PP may be formed on the semiconductor substrate 100 to extend in the second direction D2. The sacrificial patterns PP may be formed to cover top surfaces of the device isolation patterns ST and side and top surfaces of the stacking patterns STP. In an example embodiment, the formation of the sacrificial patterns PP may include forming a sacrificial layer (not shown) on the semiconductor substrate 100, forming hard mask patterns MP on the sacrificial layer, and removing a portion of the sacrificial layer using the hard mask patterns MP as an etch mask to form the sacrificial patterns PP. In an example embodiment, the sacrificial pattern PP may be formed of or include polysilicon. Next, the gate spacers GS may be formed on side surfaces of the sacrificial patterns PP

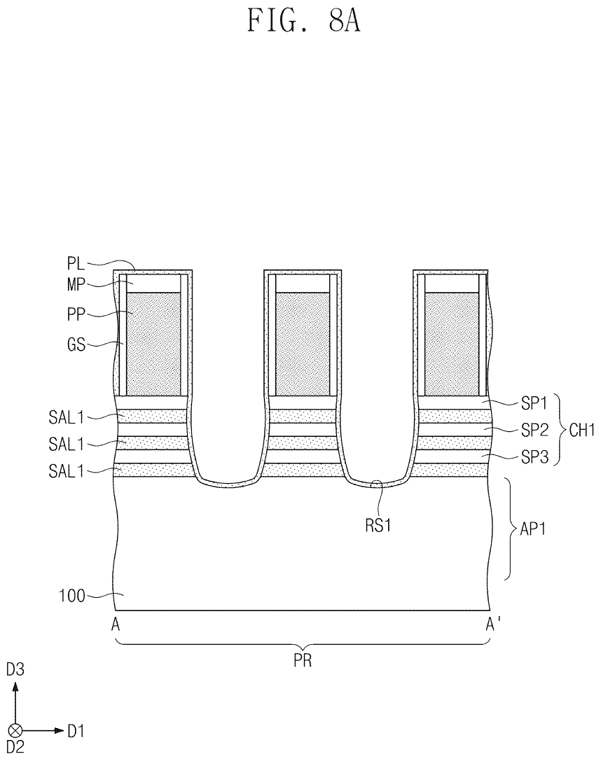

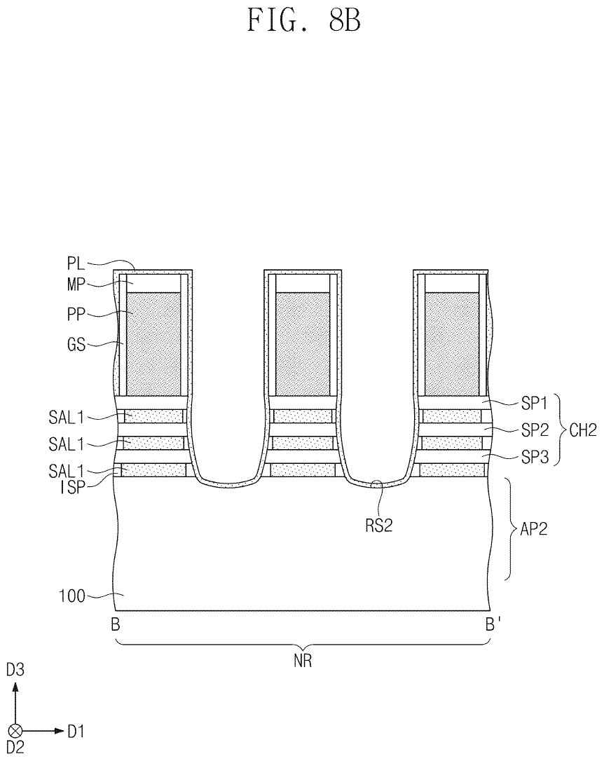

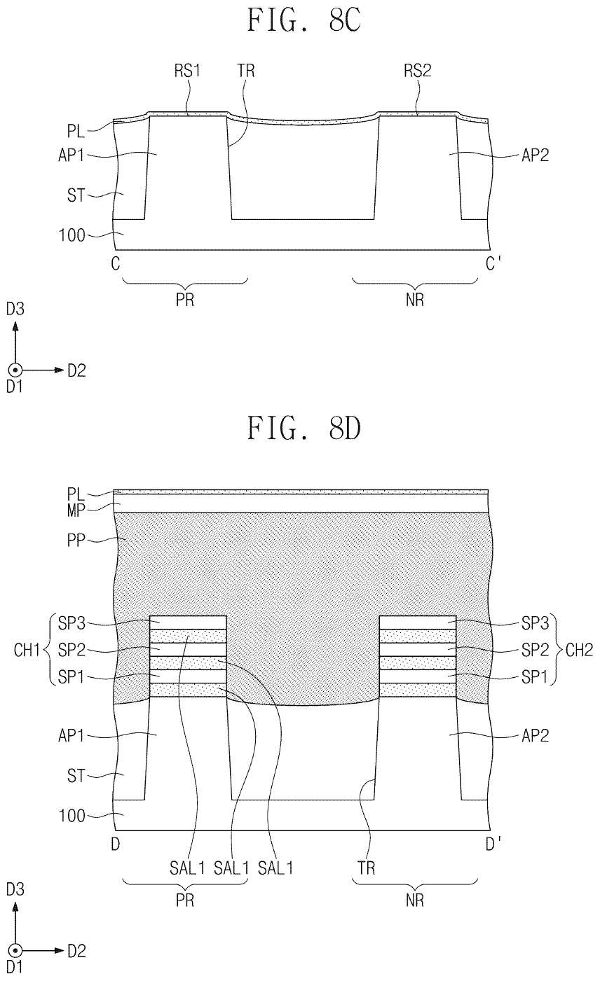

Referring to FIGS. 1 and 8A to 8D, the first recesses RS1 may be formed in the stacking pattern STP on the first active pattern AP1. The second recesses RS2 may be formed in the stacking pattern STP on the second active pattern AP2. In an example embodiment, the first and second recesses RS1 and RS2 may be formed by removing portions of the stacking pattern STP using the hard mask patterns MP as the etch mask.

The semiconductor layers SL on the first active pattern API may be divided into the first channel patterns CH1, which are separated from each other in the first direction D1, by the first recesses RS1. The semiconductor layers SL on the second active pattern AP2 may be divided into the second channel patterns CH2, which are separated from each other in the first direction D1, by the second recesses RS2. Each of the first and second channel patterns CHI and CH2 may include the first to third semiconductor patterns SP1, SP2, and SP3.

In an example embodiment, the inner spacers ISP may be formed on opposite side surfaces of the first sacrificial layer SAL1 by replacing portions of the first sacrificial layer SAL1, which are exposed by the second recess RS2, with an insulating material.

A protection layer PL may be formed to cover the entire top surface of the semiconductor substrate 100. The protection layer PL may be formed to cover side surfaces of the first and second channel patterns CH1 and CH2 and side surfaces of the first sacrificial layers SAL1. In an example embodiment, the protection layer PL may be formed of or include silicon nitride (SIN).

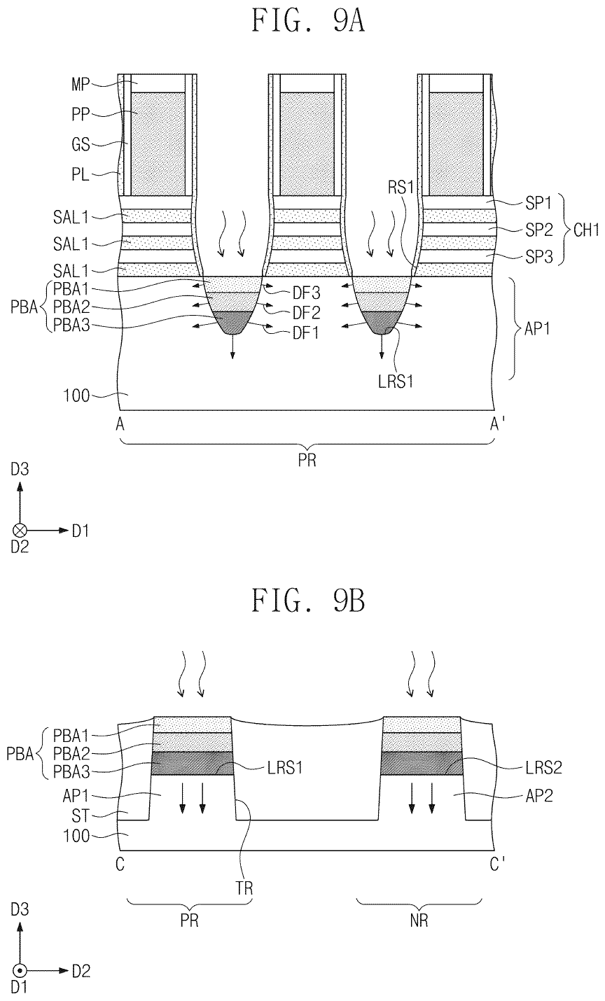

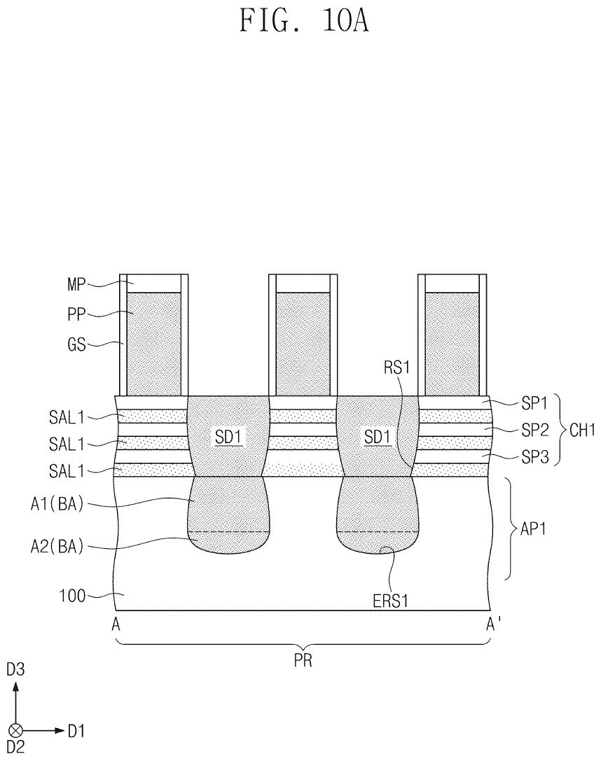

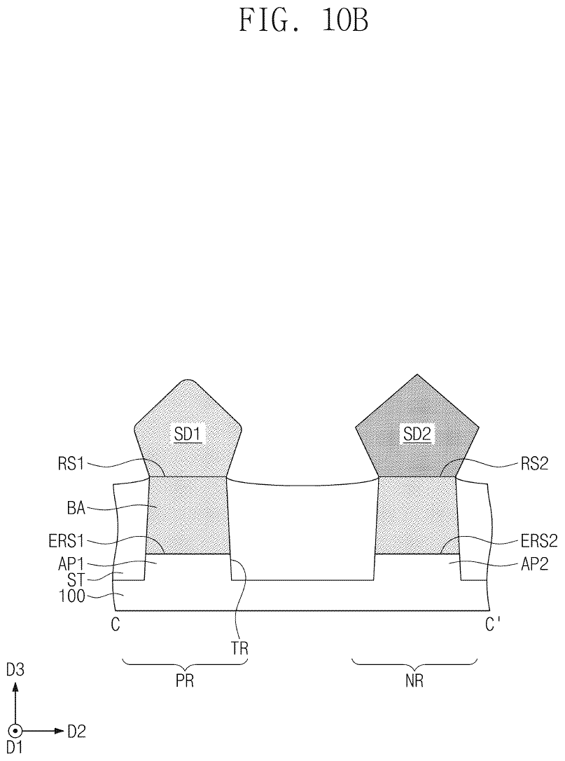

Referring to FIGS. 1, 9A, and 9B, a first lower recess LRS1 may be formed below the first recess RS1. A second lower recess LRS2 may be formed below the second recess RS2. In an example embodiment, the formation of the lower recesses LRS1 and LRS2 may include removing a portion of the protection layer PL using the hard mask patterns MP as an etch mask to expose a top surface of the semiconductor substrate 100 below the recesses RS1 and RS2 and performing a removal process on the exposed top surface of the semiconductor substrate 100. In an example embodiment, although not illustrated in the drawings, the lower recesses LRS1 and LRS2 may be formed by removing portions of the semiconductor substrate 100 below the recesses RS1 and RS2 using additional mask patterns (not shown).

A width of the lower recesses LRS1 and LRS2 in the first direction DI may decrease in a downward direction (e.g., an opposite direction of the third direction D3). The first and second channel patterns CH1 and CH2 and the first sacrificial layers SAL1, which are covered with the protection layer PL, may not be removed during the removal process, which is performed to form the lower recesses LRS1 and LRS2.

A preliminary backside alignment pattern PBA may be formed to fill the lower recess LRS1 or LRS2. Depending on (or based on) the profile of the lower recesses LRS1 and LRS2, a width of the preliminary backside alignment pattern PBA in the first direction D1 may decrease in a downward direction.

In an example embodiment, the formation of the preliminary backside alignment pattern PBA may include performing a SEG process, in which the semiconductor substrate 100 is used as a seed layer, to form a first preliminary backside alignment pattern PBA1 filling a portion of the lower recess LRS1 or LRS2, performing a SEG process, in which the first preliminary backside alignment pattern PBA1 is used as a seed layer, to form a second preliminary backside alignment pattern PBA2 on the first preliminary backside alignment pattern PBA1, and performing a SEG process, in which the second preliminary backside alignment pattern PBA2 is used as a seed layer, to form a third preliminary backside alignment pattern PBA3 filling a remaining portion of the lower recess LRS1 or LRS2. The first to third preliminary backside alignment patterns PBA1, PBA2, and PBA3 may not be formed on the first and second channel patterns CH1 and CH2 covered with the protection layer PL.

Each of the first to third preliminary backside alignment patterns PBA1, PBA2, and PBA3 may be formed of or include silicon-germanium (SiGe). In an example embodiment, an atomic concentration of germanium in the first preliminary backside alignment pattern PBA1 may be the highest among the first to third preliminary backside alignment patterns PBA1, PBA2, and PBA3, and an atomic concentration of germanium in the third preliminary backside alignment pattern PBA3 may be the lowest. For example, the atomic concentration of germanium in the first preliminary backside alignment pattern PBA1 may be higher than or equal to 50 at %, the atomic concentration of germanium in the second preliminary backside alignment pattern PBA2 may range from 20 at % to 50 at %, and the atomic concentration of germanium in the third preliminary backside alignment pattern PBA3 may be higher than 0 at % and lower than 20 at %.

The formation of the preliminary backside alignment pattern PBA is not limited to the afore-described method of forming three preliminary backside alignment patterns. For example, the formation of the preliminary backside alignment pattern PBA may include forming one or more preliminary backside alignment patterns. In the case where one preliminary backside alignment pattern PBA is formed, the preliminary backside alignment pattern PBA may be formed through a single process. For example, in such a case, a flow rate of a Ge-containing source gas, which is supplied into a chamber to form the preliminary backside alignment pattern PBA, may decrease over time during the process of forming the preliminary backside alignment pattern PBA. As a result, an atomic concentration of germanium in the preliminary backside alignment pattern PBA may increase as a vertical level is lowered.

As another example, two preliminary backside alignment patterns may be sequentially formed, and, for example, in such a case, an atomic concentration of germanium in the preliminary backside alignment pattern formed first may be equal to or higher than 20 at %, and an atomic concentration of germanium in the preliminary backside alignment pattern formed later may be higher than 0 at % and may be lower than 20 at %.

After the formation of the preliminary backside alignment pattern PBA, a thermal treatment process may be performed on the preliminary backside alignment pattern PBA. The highest temperature in the thermal treatment process may be 950° C. or higher. During the thermal treatment process, germanium atoms in the preliminary backside alignment pattern PBA may be diffused into the semiconductor substrate 100. A diffusion length of the germanium atoms caused by the thermal treatment process may be a first diffusion length DF1 in the first preliminary backside alignment pattern PBA1, a second diffusion length DF2 in the second preliminary backside alignment pattern PBA2, and a third diffusion length DF3 in the third preliminary backside alignment pattern PBA3.

In some example embodiments, the higher the atomic concentration of germanium in the preliminary backside alignment pattern PBA, the longer the germanium diffusion length into the semiconductor substrate 100 caused by the thermal treatment process. For example, among the first to third diffusion lengths DF1, DF2, and DF3, the first diffusion length DF1 may be the largest, and the third diffusion length DF3 may be the smallest.

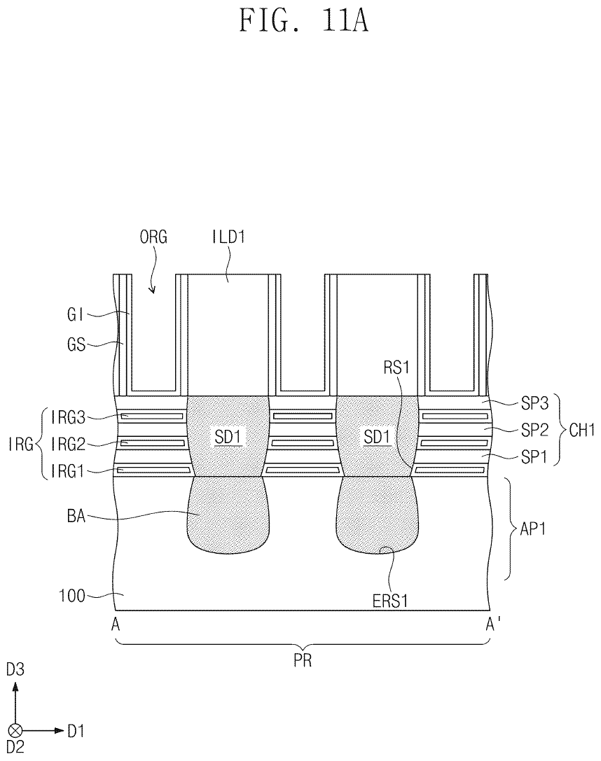

Referring to FIGS. 1, 10A, and 10B, the differences between the first to third diffusion lengths DF1, DF2, and DF3 caused by the thermal treatment process of FIGS. 1, 9A, and 9B may lead to a change in the profile of the preliminary backside alignment pattern PBA, and as a result, the backside alignment pattern BA may be formed. For example, the backside alignment pattern BA may be formed to have a first alignment region A1, which has a width in the first direction D1 that increases downward, and a second alignment region A2, which has a width in the first direction D1 that decreases downward, unlike the preliminary backside alignment pattern PBA having a width in the first direction D1 that monotonically decreases downward. A height of the first alignment region A1 may be larger than a height of the second alignment region A2.

As a result, an enlarged recess ERS1 or ERS2 may be formed to have a bottom surface that is defined by a contact surface between the backside alignment pattern BA and the semiconductor substrate 100. Owing to the profile of the backside alignment pattern BA, the enlarged recess ERS1 or ERS2 may have a width in the first direction D1 that increases and then decreases as a vertical level is lowered.

The protection layer PL may be removed from the semiconductor substrate 100.

The first source/drain patterns SD1 may be formed in the first recesses RS1. The first source/drain patterns SD1 may be formed through a SEG process using the first to third semiconductor patterns SP1, SP2, and SP3 and the backside alignment pattern BA, which are placed on the PMOSFET region PR, as a seed layer.

As an example, during the formation of the first source/drain pattern SD1, p-type impurities (e.g., boron, gallium, or indium) may be injected in-situ into the first source/drain pattern SD1. As another example, the impurities may be injected into the first source/drain pattern SD1, after the formation of the first source/drain pattern SD1.

The second source/drain patterns SD2 may be formed in the second recesses RS2 described with reference to FIG. 8B. The second source/drain patterns SD2 may be formed through a SEG process using the first to third semiconductor patterns SP1, SP2, and SP3 and the backside alignment pattern BA, which are placed on the NMOSFET region NR described with reference to FIG. 8B, as a seed layer.

As an example, during the formation of the second source/drain pattern SD2, n-type impurities (e.g., phosphorus, arsenic, or antimony) may be injected in-situ into the second source/drain pattern SD2. As another example, the impurities may be injected into the second source/drain pattern SD2, after the formation of the second source/drain pattern SD2.

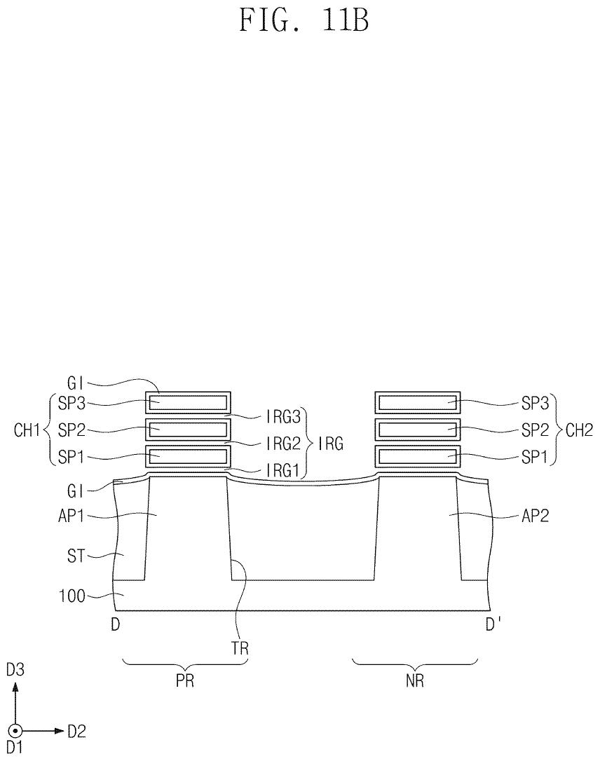

Referring to FIGS. 1, 11A, and 11B, the first interlayer insulating layer ILD1 may be formed to cover the first and second source/drain patterns SD1 and SD2, the hard mask patterns MP, and the gate spacers GS. Thereafter, the first interlayer insulating layer ILD1 may be removed from top surfaces of the sacrificial patterns PP. In an example embodiment, when the removal process is performed, the hard mask patterns MP may be removed to expose the sacrificial patterns PP.

Next, the exposed sacrificial patterns PP may be removed to form an outer region ORG. The first and second channel patterns CH1 and CH2 and the first sacrificial layers SAL1 may be exposed to the outside through the outer region ORG.

Thereafter, the first sacrificial layers SAL1 exposed may be selectively removed. Due to the high etch selectivity of the first sacrificial layers SAL1, the first to third semiconductor patterns SP1, SP2, and SP3 may not be removed or may be slightly removed.

As a result of the removal of the first sacrificial layers SAL1, inner regions IRG may be formed in regions, from which the first sacrificial layers SAL1 are removed. For example, the inner regions IRG may be formed between the first to third semiconductor patterns SP1, SP2, and SP3. The inner regions IRG may include first to third inner regions IRGI, IRG2, and IRG3, which are spaced apart from each other in the third direction D3.

The gate insulating pattern G1 may be formed in each of the inner regions IRG and in the outer region ORG. The gate insulating pattern G1 may be formed to enclose each of the first to third semiconductor patterns SP1, SP2, and SP3.

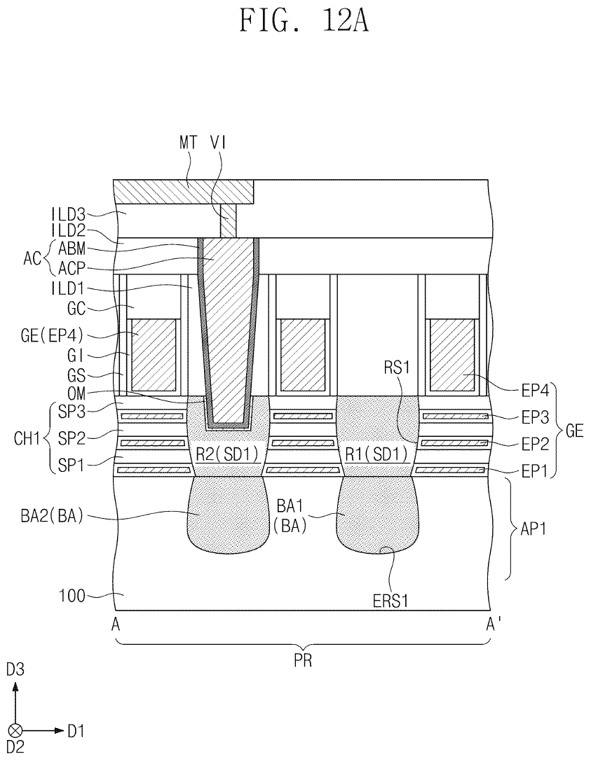

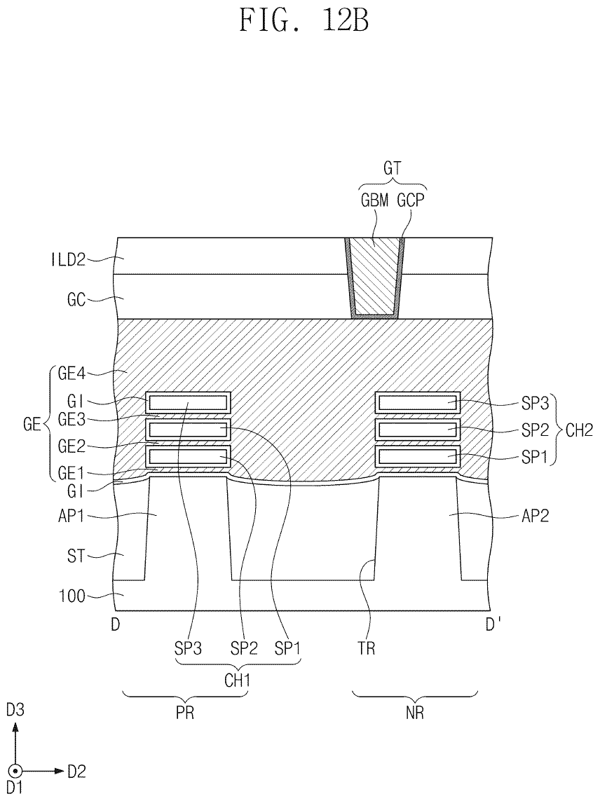

Referring to FIGS. 1, 12A, and 12B, the gate electrode GE may be formed on the gate insulating pattern G1. The gate electrode GE may include an inner electrode (e.g., the first to third electrode portions EP1, EP2, and EP3), which is formed in each of the first to third inner regions IRG1, IRG2, and IRG3, and an outer electrode (e.g., the fourth electrode portion EP4), which is formed in the outer region ORG. Thereafter, the gate capping pattern GC may be formed on the fourth electrode portion EP4.

The second interlayer insulating layer ILD2 may be formed on the first interlayer insulating layer ILD1 and the gate capping pattern GC. The active contacts AC may be formed to penetrate the first and second interlayer insulating layers ILD1 and ILD2 and may be connected to the first and second source/drain patterns SD1 and SD2, respectively. The source/drain pattern SD1 or SD2 may include the first pattern R1, which is not connected to the active contact AC, and the second pattern R2, which is connected to the active contact AC. The backside alignment pattern BA may include a first backside alignment pattern BA1 below the first pattern R1 of the source/drain pattern SD1 or SD2 and a second backside alignment pattern BA2 below the second pattern R2 of the source/drain pattern SD1 or SD2.

The formation of the active contacts AC may include forming the barrier pattern ABM and forming the conductive pattern ACP on the barrier pattern ABM. The ohmic pattern OM may be further formed between the active contact AC and the second pattern R2 of the source/drain pattern SD1 or SD2.

Gate contacts GT may be formed to penetrate the second interlayer insulating layer ILD2 and the gate capping pattern GC and may be connected to the gate electrodes GE. The formation of the gate contacts GT may include forming a gate barrier pattern GBM and forming a gate conductive pattern GCP on the gate barrier pattern GBM.

The third interlayer insulating layer ILD3 may be formed on the second interlayer insulating layer ILD2 and the active contacts AC. The metal patterns MT and the vias VI may be formed in the third interlayer insulating layer ILD3.

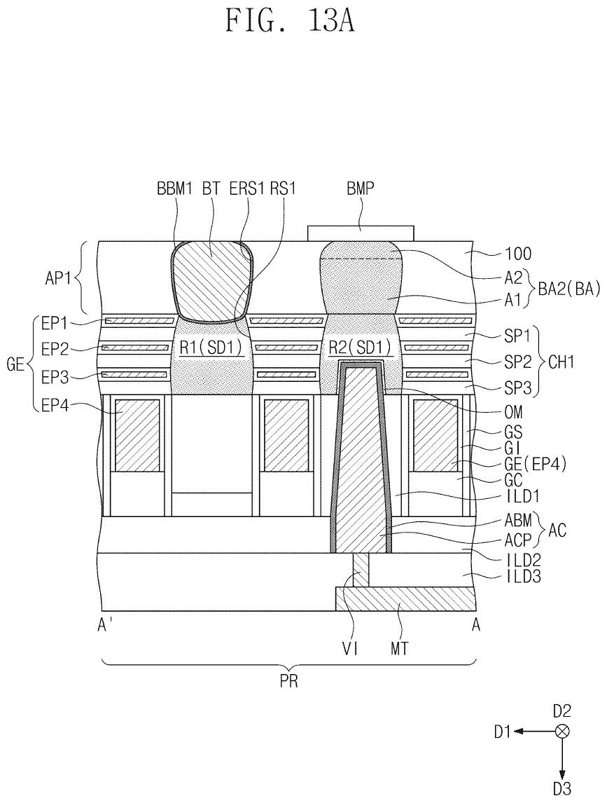

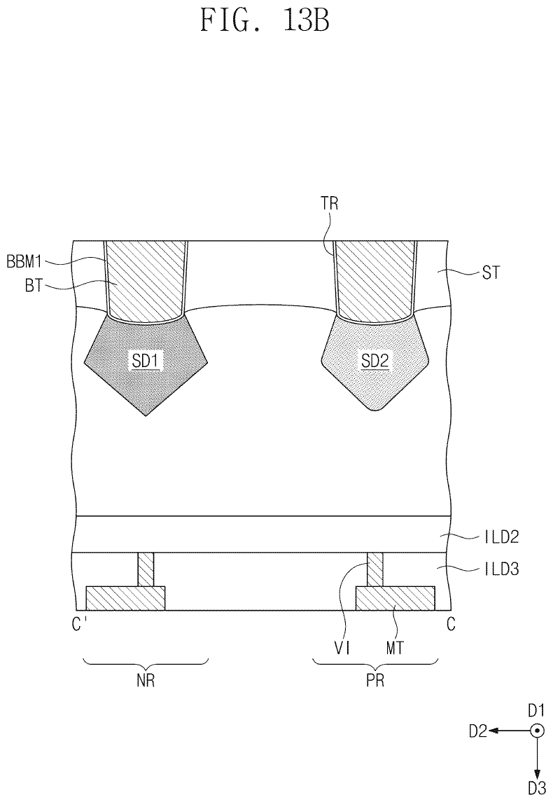

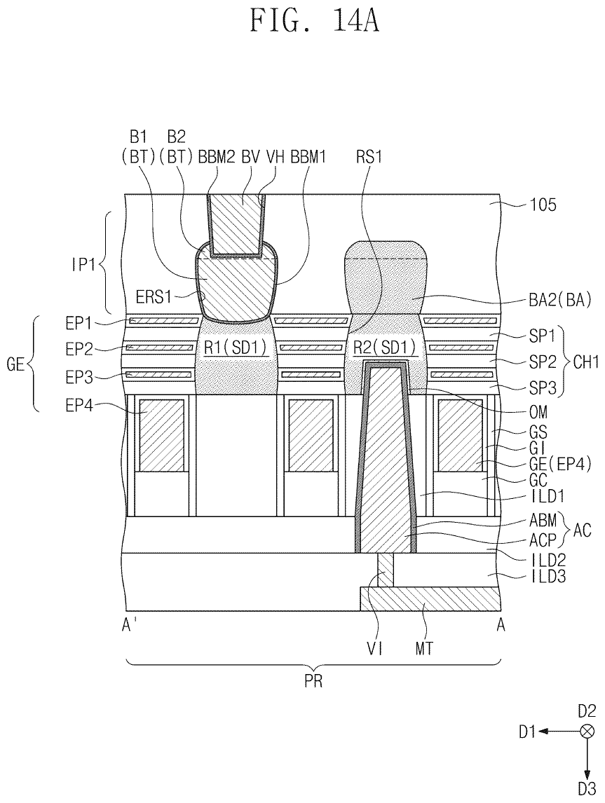

Referring to FIGS. 1, 13A, and 13B, the semiconductor substrate 100 may be inverted, after a BEOL process. Given that the semiconductor substrate 100 is inverted, the terminologies ‘top surface’ and ‘upper portion’ in the following description of FIGS. 13A to 14B should be understood as referring to the ‘bottom surface’ and ‘lower portion’, respectively, in the final structure of the semiconductor device described with reference to FIGS. 2A to 2C, and the terminologies ‘bottom surface’ and ‘lower portion’ should be understood as referring to the ‘top surface’ and ‘upper portion’, respectively, in the final structure of the semiconductor device described with reference to FIGS. 2A to 2C. Similarly, within this context, the terms ‘below’ and ‘on’ should be interpreted inversely. For example, ‘below’ refers to ‘on’, and ‘on’ refers to ‘below’ in the final structure of the semiconductor device of FIGS. 2A to 2C.

A removal process may be performed on an upper portion of the semiconductor substrate 100. The removal process may be performed to expose top surfaces of the first and second backside alignment patterns BA1 and BA2.

A backside mask pattern BMP may be formed to cover a top surface of the second backside alignment pattern BA2. The backside mask pattern BMP may not cover a top surface of the first backside alignment pattern BA1.

The first backside alignment pattern BA1 may be removed from the semiconductor substrate 100 using the backside mask pattern BMP as an etch mask. Accordingly, a top surface of the first pattern R1 of the source/drain pattern SD1 or SD2 and an inner surface of the enlarged recess ERS1 or ERS2 on the first pattern R1 may be exposed.

The first backside barrier pattern BBM1 may conformally cover the exposed top surface of the first pattern R1 of the source/drain pattern SD1 or SD2 and the exposed inner surface of the enlarged recess ERS1 or ERS2 on the first pattern R1. The backside conductive contact BT may be formed to fill a remaining portion of the exposed enlarged recess ERS1 or ERS2.

According to an example embodiment, the downward narrowing profile of the lower recesses LRS1 and LRS2 may be changed by the afore-described fabrication method. For example, each of the enlarged recesses ERS1 and ERS2 may be formed to have a width in the first direction D1 that increases and then decreases, as one moves in an opposite direction of the third direction D3.

If an element is formed in a recess whose width in the first direction D1 decreases in an upward direction, a seam or a void may be formed in the element. However, in most portions of the enlarged recess ERS1 or ERS2, a width of the enlarged recess ERS1 or ERS2 in the first direction D1 may increase in an upward direction. Accordingly, the enlarged recess ERS1 or ERS2 may be easily filled with the backside conductive contact BT, and as a result, any seam or void may not be formed in the backside conductive contact BT. Accordingly, the electrical characteristics (and/or reliability) of the semiconductor device may be improved.

Referring to FIGS. 1, 14A, and 14B, the backside mask pattern BMP may be removed from the semiconductor substrate 100. Thereafter, the semiconductor substrate 100 may be completely removed (or may be removed). The substrate 105 may be formed by forming an insulating material to a thickness that is larger than a thickness of the removed semiconductor substrate 100 or is at least larger than a thickness of the first backside alignment pattern BA1.

A via hole VH may be formed to penetrate the substrate 105, and thus, the backside conductive contact BT may be exposed through the via hole VH. The second backside barrier pattern BBM2 may be formed to conformally cover an inner surface of the via hole VH and a top surface of the backside conductive contact BT. Next, the backside via pattern BV may be formed to fill a remaining portion of the via hole VH. The backside via pattern BV and the backside conductive contact BT may form the backside conductive structure BCS.

According to an example embodiment, the backside conductive contact BT may include the first region B1, which has an increasing width in the first direction DI as a vertical distance from the source/drain pattern SD1 or SD2 increases, and the second region B2, which has a decreasing width in the first direction D1 as a vertical distance from the first region B1 increases. A height of the first region B1 may be larger than a height of the second region B2. Accordingly, a contact area between the backside via pattern BV and the backside conductive contact BT having the first and second regions B1 and B2 may be larger than a contact area between the backside via pattern BV and the backside conductive contact BT having only the second region B2. As a result, even when the backside via pattern BV is misaligned, the backside via pattern BV may be in contact with the backside conductive contact BT having the first and second regions B1 and B2. Thus, the electrical characteristics (and/or reliability) and productivity of the semiconductor device may be improved.

Referring to FIGS. 1 and 2A to 2C, the lower power line BPR may be formed on the substrate 105. The lower power line BPR may be formed to be electrically connected to the backside conductive structure BCS. The power delivery network layer PDN may be formed on the lower power line BPR. The power delivery network layer PDN may be formed to allow for the application of a source or drain voltage to the lower power line BPR.

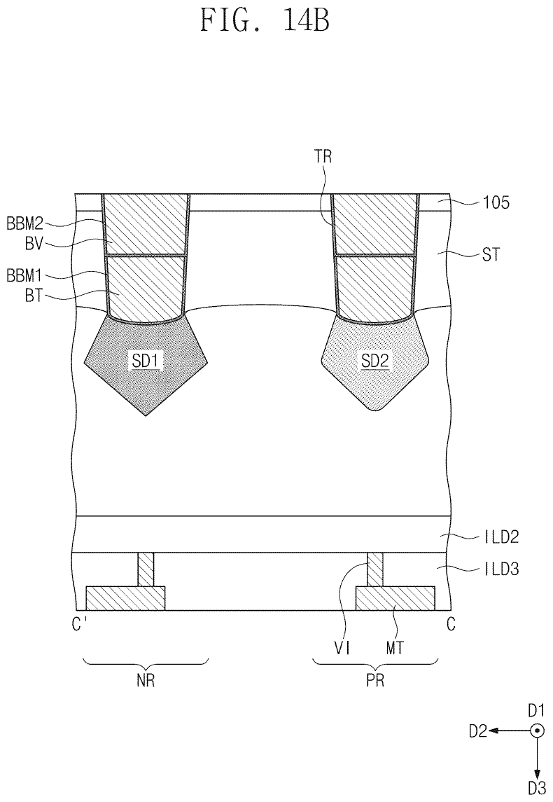

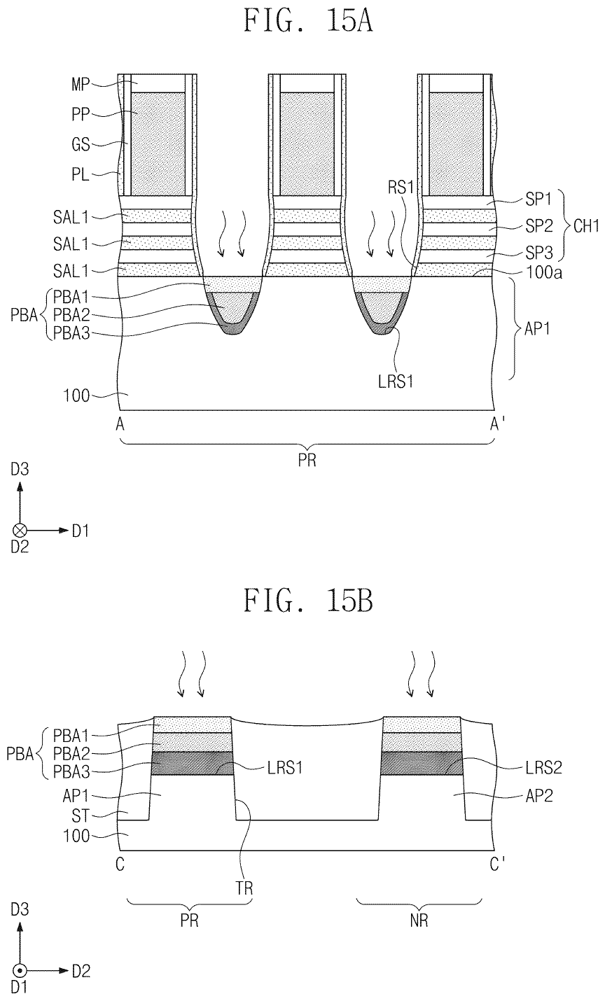

FIGS. 15A and 15B are sectional views illustrating a method of fabricating a semiconductor device according to an example embodiment.

Referring to FIGS. 1, 15A, and 15B, the first to third preliminary backside alignment patterns PBA1, PBA2, and PBA3 may be formed by a different method from that described with reference to FIGS. 1, 9A, and 9B.

A SEG process using the semiconductor substrate 100 as a seed layer may be performed to form the first preliminary backside alignment pattern PBA1 conformally covering an inner surface of the lower recess LRS1 or LRS2, after the formation of the lower recess LRS1 and LRS2 described with reference to FIGS. 1, 9A, and 9B.

Next, a SEG process using the first preliminary backside alignment pattern PBA1 as a seed layer may be performed to form the second preliminary backside alignment pattern PBA2 filling a remaining portion of the lower recess LRS1 or LRS2.

Thereafter, each of the first and second preliminary backside alignment patterns PBA1 and PBA2 may be partially removed (or may be removed). Next, a SEG process using the first and second preliminary backside alignment patterns PBA1 and PBA2 as a seed layer may be performed to form the third preliminary backside alignment pattern PBA3 filling a remaining portion of the lower recess LRS1 or LRS2.

Subsequent steps of the fabrication process may be performed using the method described above, and, in such a case, the semiconductor device may be fabricated to have the structure described with reference to FIGS. 1 to 2A to 2C.

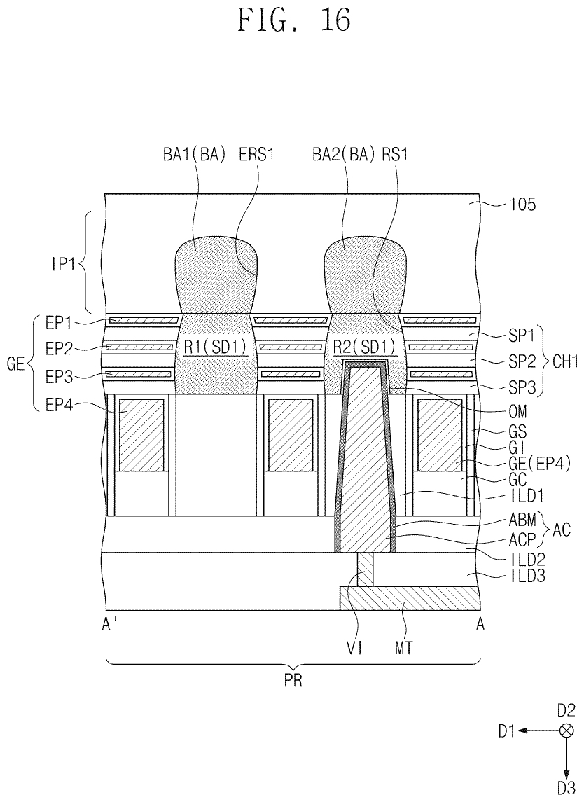

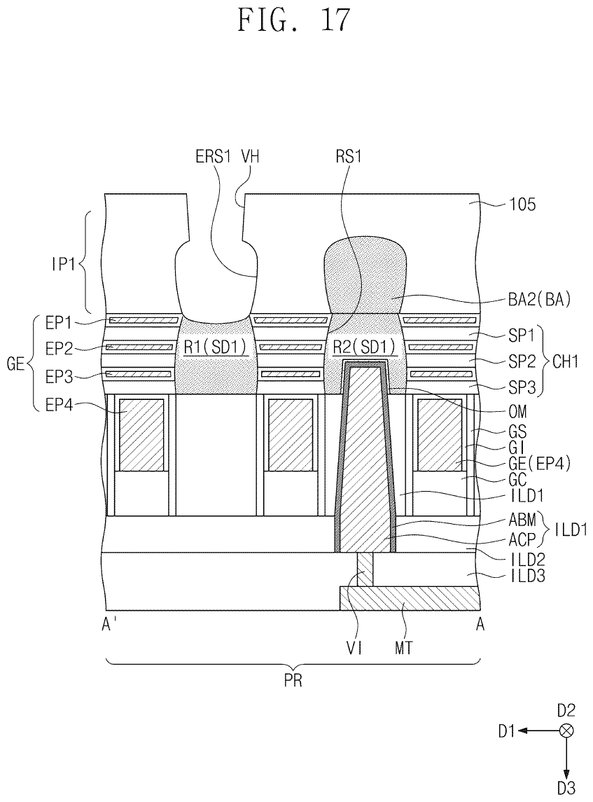

FIGS. 16 and 17 are sectional views illustrating a method of fabricating a semiconductor device according to an example embodiment.

Referring to FIGS. 1 and 16, the semiconductor substrate 100 may be completely removed (or may be removed), after the process of inverting the semiconductor substrate 100 described with reference to FIGS. 1, 13A, and 13B. The substrate 105 may be formed by forming an insulating material to a thickness that is larger than a thickness of the removed semiconductor substrate 100 or is at least larger than a thickness of the first backside alignment pattern BA1.

Referring to FIGS. 1 and 17, the via hole VH may be formed on the first backside alignment pattern BAI to penetrate the substrate 105. Accordingly, the first backside alignment pattern BA1 may be exposed.

Thereafter, the exposed first backside alignment pattern BA1 may be removed from the substrate 105. Accordingly, a top surface of the first pattern R1 of the source/drain pattern SD1 or SD2 and an inner surface of the enlarged recess ERS1 or ERS2 on the first pattern R1 may be exposed.

Referring to FIGS. 1 and 4A to 4C, the backside barrier pattern BBM may be formed to conformally cover an inner surface of the via hole VH, an inner surface of the enlarged recess ERS1 or ERS2, and the top surface of the first pattern R1 of the source/drain pattern SD1 or SD2. Thereafter, the backside conductive structure BCS may be formed to fill a remaining portion of each of the enlarged recess ERS1 or ERS2 and the via hole VH.

Subsequent steps of the fabrication process may be performed using the method described above, and, in such a case, the semiconductor device may be fabricated to have the structure described with reference to FIGS. 1 and 4A to 4C.

According to an example embodiment, a lower recess may be formed in a substrate. In some example embodiments, a width of the lower recess in a first direction may decrease in a downward direction. An atomic concentration of germanium in a preliminary backside alignment pattern, which is formed in the lower recess, may increase in a downward direction. A thermal treatment process may be performed on the preliminary backside alignment pattern. Due to a change in diffusion length caused by a change in an atomic concentration of germanium, the profiles of the preliminary backside alignment pattern and the lower recess may be changed during the thermal treatment process. As a result, a backside alignment pattern and an enlarged recess may be formed to have a width in the first direction that increases and then decreases, as a vertical level is lowered.

In some example embodiments, when the backside alignment pattern is removed and a backside conductive contact is formed in the enlarged recess, the enlarged recess may be easily filled with the backside conductive contact. In some example embodiments, a seam and a void may not be formed in the backside conductive contact, and thus, the electrical characteristics (and/or reliability) of the semiconductor device may be improved.

In addition, the backside conductive contact may include a first region whose width in the first direction increases as a distance from a source/drain pattern increases, and a second region whose width in the first direction decreases as a distance from the first region increases. A height of the first region may be larger than a height of the second region. Accordingly, a contact area between the backside conductive contact and a backside via pattern may be larger when the backside conductive contact includes the first and second regions than when the backside conductive contact includes only the second region. As a result, even when the backside via pattern is misaligned, the backside via pattern may be in contact with the backside conductive contact, which has the first and second regions. Thus, the electrical characteristics (and/or reliability) and productivity of the semiconductor device may be improved.

While some example embodiments of inventive concepts have been shown and described, it will be understood by one of ordinary skill in the art that variations in form and detail may be made therein without departing from the spirit and scope of the attached claims.

What is claimed is:

1. A semiconductor device, comprising:
a substrate;
a lower power line buried in the substrate and extending in a first direction parallel to a bottom surface of the substrate;
a source/drain pattern on the substrate; and
a backside contact structure provided to penetrate the substrate and electrically connect the lower power line to the source/drain pattern,
wherein the backside contact structure includes a backside via pattern and a backside conductive contact sequentially arranged on the lower power line,
wherein a side surface of the backside conductive contact is convex in an outward direction from an inner portion of the backside conductive contact toward an outside, and
wherein a width of the backside conductive contact in the first direction is greater at a first level, such that the width of the backside conductive contact in the first direction increases as a distance from the source/drain pattern increases in a direction toward the first level.

2. The semiconductor device of claim 1, further comprising a backside barrier pattern between the backside conductive contact and the backside via pattern.

3. The semiconductor device of claim 1, wherein the backside conductive contact and the backside via pattern are connected to each other without any interface therebetween.

4. The semiconductor device of claim 1, wherein a distance from the first level to an uppermost surface of the backside conductive contact is larger than a distance from the first level to a lowermost surface of the backside conductive contact.

5. The semiconductor device of claim 1, wherein the backside conductive contact comprises a first region at a level higher than the first level, and a second region at a level lower than the first level, and
wherein a width of the second region in the first direction decreases as a distance from the source/drain pattern increases.

6. The semiconductor device of claim 5, wherein a height of the first region is larger than a height of the second region.

7. The semiconductor device of claim 1, wherein a width of the backside via pattern in the first direction increases as a distance from the source/drain pattern increases.

8. The semiconductor device of claim 1, wherein the source/drain pattern comprises a pair of source/drain patterns adjacent to each other in the first direction,
wherein the backside contact structure is in contact with one of the pair of source/drain patterns, and
wherein the semiconductor device further comprises a backside alignment pattern that is in contact with the other of the pair of source/drain patterns and includes silicon-germanium (SiGe).

9. The semiconductor device of claim 1, wherein the backside conductive contact has a first side surface arranged on the first level, and a second side surface arranged below the first level, and
wherein a curvature of the second side surface is larger than a curvature of the first side surface.

10. The semiconductor device of claim 1, wherein the backside conductive contact covers a top surface of the backside via pattern.

11. A semiconductor device, comprising:
a substrate;
a lower power line buried in the substrate and extending in a first direction parallel to a bottom surface of the substrate;
a source/drain pattern on the substrate; and
a backside contact structure penetrating the substrate and electrically connecting the lower power line to the source/drain pattern,
wherein the backside contact structure comprises a backside via pattern and a backside conductive contact sequentially arranged on the lower power line, and
wherein the backside conductive contact comprises a first region having a width in the first direction that increases as a distance from the source/drain pattern increases in a downward direction and a second region having a width in the first direction that decreases as a distance from the first region increases in a downward direction.

12. The semiconductor device of claim 11, wherein a height of the first region is greater than a height of the second region.

13. The semiconductor device of claim 11, wherein a width of the backside via pattern in the first direction increases as a distance from the source/drain pattern increases.

14. The semiconductor device of claim 11, wherein a side surface of each of the first and second regions is convex in an outward direction from an inner portion of the backside conductive contact toward an outside.

15. The semiconductor device of claim 11, wherein a curvature of a side surface of the second region is larger than a curvature of a side surface of the first region.

16. The semiconductor device of claim 11, wherein the source/drain pattern comprises a pair of source/drain patterns adjacent to each other in the first direction,
wherein the backside contact structure is in contact with one of the pair of source/drain patterns, and
wherein the semiconductor device further comprises a backside alignment pattern in contact with the other of the pair of source/drain patterns and includes silicon-germanium (SiGe).

17. The semiconductor device of claim 11, wherein the second region covers a top surface of the backside via pattern.

18. A semiconductor device, comprising:
a substrate;
a lower power line in the substrate and extending parallel to a bottom surface of the substrate;
a source/drain pattern on the substrate;
a channel pattern on the substrate, the channel pattern including a plurality of semiconductor patterns stacked to be spaced apart from each other;
a gate electrode between the plurality of semiconductor patterns; and
a backside contact structure penetrating the substrate and electrically connecting the lower power line to the source/drain pattern,
wherein the backside contact structure comprises a backside via pattern and a backside conductive contact sequentially arranged on the lower power line,
wherein a side surface of the backside conductive contact is convex in an outward direction from an inner portion of the backside conductive contact toward an outside, and
wherein a width of the backside conductive contact measured in a first direction parallel to the bottom surface of the substrate is greater at a first level and increases as a distance from the source/drain pattern increases in a direction toward the first level.

19. The semiconductor device of claim 18, wherein the backside conductive contact comprises a first region at a level higher than the first level, and a second region at a level lower than the first level, and
wherein a width of the second region in the first direction decreases as a distance from the source/drain pattern increases.

20. The semiconductor device of claim 19, wherein an area of the first region is larger than an area of the second region, when viewed in a sectional view.
